(19) United States
(12) Patent Application Publication
(10) Pub. No.: US 2024/0423028 A1
(43) Pub. Date: Dec. 19, 2024

(54) DISPLAY DEVICE AND MANUFACTURING METHOD OF DISPLAY DEVICE

(71) Applicant: Japan Display Inc., Tokyo (JP)

(72) Inventors: Takanobu TAKENAKA, Tokyo (JP); Kaichi FUKUDA, Tokyo (JP); Masaru TAKAYAMA, Tokyo (JP); Hirofumi MIZUKOSHI, Tokyo (JP); Yuki HAMADA, Tokyo (JP)

(73) Assignee: Japan Display Inc., Tokyo (JP)

(21) Appl. No.: 18/731,422

(22) Filed: Jun. 3, 2024

(30) Foreign Application Priority Data
Jun. 13, 2023 (JP) 2023-097111

(51) Int. Cl. H10K 59/122; H10K 59/12; H10K 71/16

(52) U.S. Cl. CPC H10K 59/122; H10K 59/1201; H10K 71/164

(57) ABSTRACT

According to one embodiment, a display device includes a substrate, a lower electrode, a rib, a partition having lower and upper portions, an organic layer, and an upper electrode. The partition has first and second partitions. The upper portion of the first partition has a first end portion. The upper portion of the second partition has a second end portion. A thickness of the organic layer immediately under the first end portion is less than that of the organic layer immediately under the second end portion. A thickness of the upper electrode immediately under the first end portion is greater than that of the upper electrode immediately under the second end portion.

### CROSS-REFERENCE TO RELATED APPLICATION

This application is based upon and claims the benefit of priority from Japanese Patent Application No. 2023-097111, filed Jun. 13, 2023, the entire contents of which are incorporated herein by reference.

### FIELD

Embodiments described herein relate generally to a display device and a manufacturing method of a display device.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer. Common voltage is applied to the upper electrode of each display element through lines provided in a display area.

The organic layer and the upper electrode are formed by vapor deposition relative to a substrate on which the lines described above are provided. In this case, there is a possibility that the connection between the upper electrode and the lines is interrupted by the organic layer which is formed earlier.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is a schematic cross-sectional view of the display device along the III-III line of FIG. 2.

FIG. 4 is a diagram showing an example of a layer structure which could be applied to an organic layer.

FIG. 5 is a schematic cross-sectional view of the display device along the V-V line of FIG. 2.

FIG. 6 is a schematic plan view of a partition which surrounds subpixels.

FIG. 7 is a flowchart showing an example of the manufacturing method of the display device.

FIG. 8A is a schematic cross-sectional view showing the manufacturing process of the display device.

FIG. 8B is a schematic cross-sectional view showing a manufacturing process following FIG. 8A.

FIG. 8C is a schematic cross-sectional view showing a manufacturing process following FIG. 8B.

FIG. 8D is a schematic cross-sectional view showing a manufacturing process following FIG. 8C.

FIG. 8E is a schematic cross-sectional view showing a manufacturing process following FIG. 8D.

FIG. 8F is a schematic cross-sectional view showing a manufacturing process following FIG. 8E.

FIG. 8G is a schematic cross-sectional view showing a manufacturing process following FIG. 8F.

FIG. 9 is a diagram showing the schematic configuration of part of the manufacturing equipment of the display device.

FIG. 10 is a schematic perspective view showing an example of an evaporation source.

FIG. 11 is a schematic perspective view showing another example which can be applied to an evaporation source.

FIG. 12 is a schematic plan view showing an example of the relationship between a substrate which is conveyed and an evaporation source.

FIG. 13 is a schematic cross-sectional view showing the process of forming a hole injection layer.

FIG. 14 is a schematic cross-sectional view showing the process of forming a hole transport layer, an electron blocking layer, a light emitting layer, a hole blocking layer, an electron transport layer and an electron injection layer.

FIG. 15 is a schematic cross-sectional view showing the process of forming an upper electrode.

FIG. 16 is a schematic cross-sectional view showing another example of the process of forming the upper electrode.

FIG. 17 is a schematic cross-sectional view showing the first modified example of a configuration which could be applied to the partition.

FIG. 18 is a schematic cross-sectional view showing the second modified example of a configuration which could be applied to the partition.

FIG. 19 is a schematic perspective view showing an example of a configuration which can be applied to an evaporation source according to a second embodiment.

FIG. 20 is a schematic cross-sectional view showing the process of performing vapor deposition using the evaporation source shown in FIG. 19.

FIG. 21 is a schematic cross-sectional view showing another configuration which can be applied to the evaporation source according to the second embodiment.

FIG. 22 is a schematic cross-sectional view showing yet another configuration which can be applied to the evaporation source according to the second embodiment.

FIG. 23 is a schematic cross-sectional view showing the process of performing vapor deposition using the evaporation source shown in FIG. 22.

### DETAILED DESCRIPTION

In general, according to one embodiment, a display device comprises a substrate, a lower electrode provided above the substrate, a rib having a pixel aperture which overlaps the lower electrode, a partition which has a conductive lower portion provided on the rib and an upper portion protruding from a side surface of the lower portion, an organic layer which is in contact with the lower electrode through the pixel aperture and emits light based on application of voltage, and an upper electrode which covers the organic layer and is in contact with the lower portion of the partition. The partition has first and second partitions which are provided such that the pixel aperture is interposed between the first and second partitions. The upper portion of the first partition has a first end portion which overlaps the organic layer and the upper electrode. The upper portion of the second partition has a second end portion which overlaps the organic layer and the upper electrode. A thickness of the organic layer immediately under the first end portion is less than a thickness of the organic layer immediately under the second end portion. Further, a thickness of the upper electrode immediately under the first end portion is greater than a thickness of the upper electrode immediately under the second end portion.

According to another embodiment, a manufacturing method of a display device includes preparing a substrate including a lower electrode, a rib having a pixel aperture which overlaps the lower electrode, and a partition which has a conductive lower portion provided on the rib and an upper portion protruding from a side surface of the lower portion, forming an organic layer which is in contact with the lower electrode through the pixel aperture and emits light based on application of voltage by vapor deposition, and forming an upper electrode which covers the organic layer and is in contact with the lower portion of the partition by vapor deposition. Further, the organic layer includes a first thin film.

According to an aspect of the embodiment, a first evaporation direction in which a first evaporation source used to form the first thin film emits a vaporized material inclines with respect to a normal direction of the substrate. Further, a second evaporation direction in which a second evaporation source used to form the upper electrode emits a vaporized material inclines to an opposite direction of the first evaporation direction with respect to the normal direction.

According to another aspect of the embodiment, the first evaporation source used to form the first thin film comprises a first nozzle which emits a vaporized material in the first evaporation direction, and a first shield which protrudes from the first nozzle. The second evaporation source used to form the upper electrode comprises a second nozzle which emits a vaporized material in the second evaporation direction. The second evaporation direction inclines to a first lateral direction with respect to the normal direction of the substrate. Further, the first shield has a shape in which a height on a first lateral direction side of the first nozzle is greater than a height on a second lateral direction side opposite to the first lateral direction side.

According to yet another embodiment, manufacturing equipment of a display device comprises, for a substrate including a lower electrode, a rib having a pixel aperture which overlaps the lower electrode, and a partition which has a conductive lower portion provided on the rib and an upper portion protruding from a side surface of the lower portion, a first evaporation device forming an organic layer which is in contact with the lower electrode through the pixel aperture and emits light based on application of voltage, and a second evaporation device forming an upper electrode which covers the organic layer and is in contact with the lower portion of the partition for the substrate. The organic layer includes a first thin film. The first evaporation device comprises a first evaporation source used to form the first thin film. The second evaporation device comprises a second evaporation source used to form the upper electrode.

According to an aspect of the embodiment, a first evaporation direction in which the first evaporation source emits a vaporized material inclines with respect to a normal direction of the substrate. Further, a second evaporation direction in which the second evaporation source emits a vaporized material inclines to an opposite direction of the first evaporation direction with respect to the normal direction.

According to another aspect of the embodiment, the first evaporation source comprises a first nozzle which emits a vaporized material in a first evaporation direction, and a first shield which protrudes from the first nozzle. The second evaporation source comprises a second nozzle which emits a vaporized material in a second evaporation direction. The second evaporation direction inclines to a first lateral direction with respect to a normal direction of the substrate. Further, the first shield has a shape in which a height on a first lateral direction side of the first nozzle is greater than a height on a second lateral direction side opposite to the first lateral direction side.

The embodiments can provide a display device, and a manufacturing method and manufacturing equipment of a display device, such that lines provided in a display area can be satisfactorily connected to the upper electrode of each display element.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

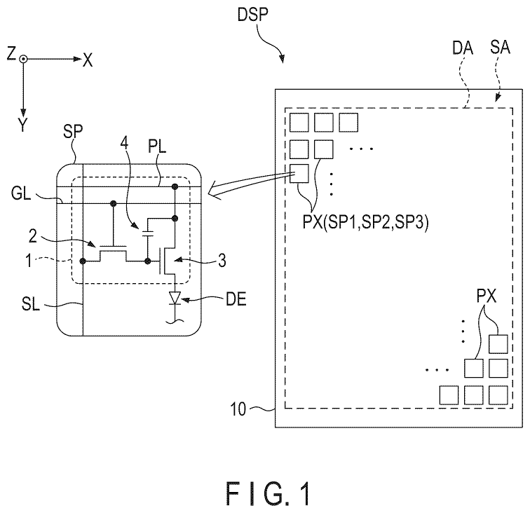

FIG. 1 is a diagram showing a configuration example of a display device DSP according to a first embodiment. The display device DSP comprises an insulating substrate 10. The substrate 10 has a display area DA which displays an image, and a surrounding area SA around the display area DA. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in an X-direction and a Y-direction. Each pixel PX includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

A plurality of scanning lines GL which supply a scanning signal to the pixel circuit 1 of each subpixel SP, a plurality of signal lines SL which supply a video signal to the pixel circuit 1 of each subpixel SP and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to the scanning line GL. One of the source electrode and drain electrode of the pixel switch 2 is connected to the signal line SL. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

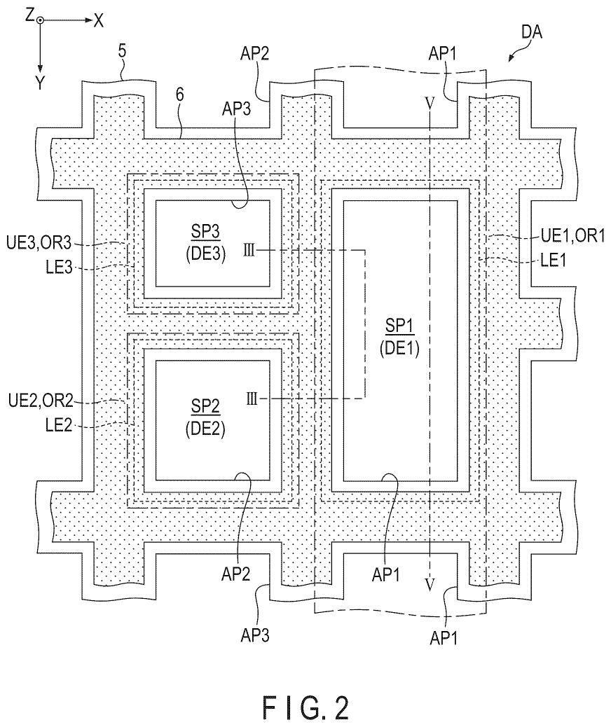

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib 5 is provided in the display area DA. The rib 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib 5 surrounds each of these display elements DE1, DE2 and DE3.

A conductive partition 6 is provided on the rib 5. The partition 6 overlaps the rib 5 as a whole and has the same planar shape as the rib 5. In other words, the partition 6 has an aperture in each of subpixels SP1, SP2 and SP3. From another viewpoint, each of the rib 5 and the partition 6 has a grating shape as seen in plan view and surrounds each of subpixels SP1, SP2 and SP3. The partition 6 functions as lines which apply common voltage to the upper electrodes UE1, UE2 and UE3.

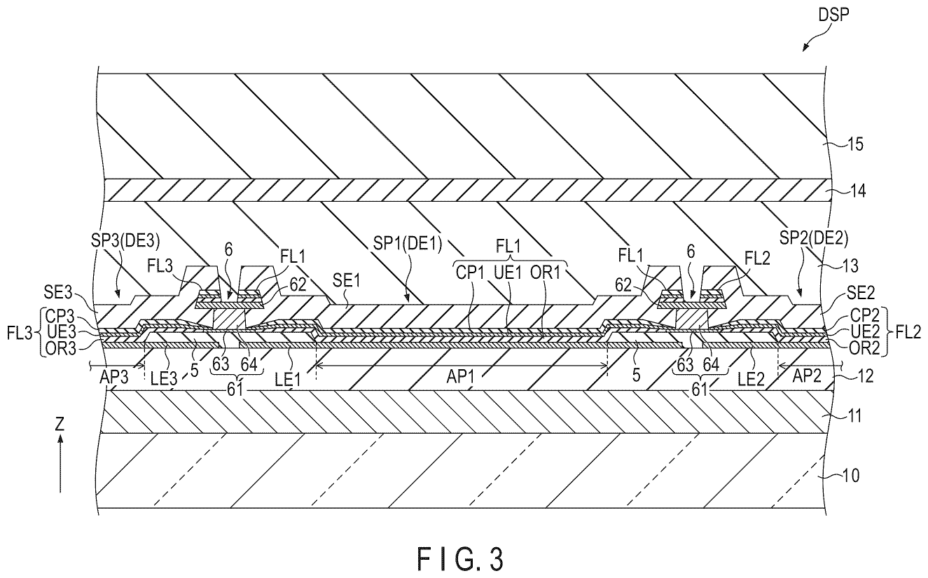

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuits 1, scanning lines GL, signal lines SL and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib 5 is provided on the organic insulating layer 12 and the lower electrodes LE1, LE2 and LE3. The end portions of the lower electrodes LE1, LE2 and LE3 are covered with the rib 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

In the example of FIG. 3, the lower portion 61 has a bottom layer 63 provided on the rib 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portions 61 of the partition 6.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located under the partition 6 (in other words, the portion which constitutes the display element DE1). Similarly, the stacked film FL2 is partly located on the upper portion 62. This portion is spaced apart from, of the stacked film FL2, the portion located under the partition 6 (in other words, the portion which constitutes the display element DE2). Further, the stacked film FL3 is partly located on the upper portion 62. This portion is spaced apart from, of the stacked film FL3, the portion located under the partition 6 (in other words, the portion which constitutes the display element DE3).

Sealing layers SE1, SE2 and SE3 are provided in subpixels SP1, SP2 and SP3, respectively. The sealing layer SE1 continuously covers the cap layer CP1 and the partition 6 around subpixel SP1. The sealing layer SE2 continuously covers the cap layer CP2 and the partition 6 around subpixel SP2. The sealing layer SE3 continuously covers the cap layer CP3 and the partition 6 around subpixel SP3.

In the example of FIG. 3, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

The sealing layers SE1, SE2 and SE3 are covered with a resin layer 13. The resin layer 13 is covered with a sealing layer 14. The sealing layer 14 is covered with a resin layer 15. The resin layers 13 and 15 and the sealing layer 14 are continuously provided in at least the entire display area DA and partly extend in the surrounding area SA as well.

A cover member such as a polarizer, a touch panel, a protective film or a cover glass may be further provided above the resin layer 15. This cover member may be attached to the resin layer 15 via, for example, an adhesive layer such as an optical clear adhesive (OCA).

The organic insulating layer 12 is formed of an organic insulating material such as polyimide. Each of the rib 5 and the sealing layers 14, SE1, SE2 and SE3 is formed of an inorganic insulating material such as silicon nitride (SiNx), silicon oxide (SiOx), silicon oxynitride (SiON) or aluminum oxide (Al₂O₃). For example, the rib 5 is formed of silicon oxynitride, and each of the sealing layers 14, SE1, SE2 and SE3 is formed of silicon nitride. Each of the resin layers 13 and 15 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

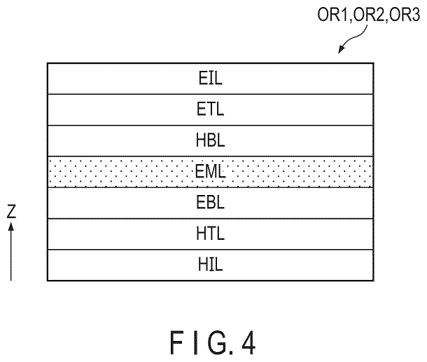

FIG. 4 is a diagram showing an example of a layer structure which could be applied to the organic layers OR1, OR2 and OR3. Each of the organic layers OR1, OR2 and OR3 consists of a plurality of thin films including a light emitting layer EML. This embodiment assumes a case where each of the organic layers OR1, OR2 and OR3 comprises a structure in which a hole injection layer HIL, a hole transport layer HTL, an electron blocking layer EBL, a light emitting layer EML, a hole blocking layer HBL, an electron transport layer ETL and an electron injection layer EIL are stacked in order in a Z-direction. It should be noted that each of the organic layers OR1, OR2 and OR3 may comprise another structure such as a tandem structure including a plurality of light emitting layers EML.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE1, SE2 and SE3. It should be noted that at least one of the cap layers CP1, CP2 and CP3 may be omitted.

Each of the bottom layer 63 and stem layer 64 of the partition 6 is formed of a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material.

For example, the upper portion 62 of the partition 6 has a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy may be used. For the conductive oxide forming the upper layer, for example, ITO or IZO may be used. It should be noted that the upper portion 62 may comprise a single-layer structure of a metal material. The upper portion 62 may further include a layer formed of an insulating material.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively, based on the video signals of the signal lines SL.

The organic layers OR1, OR2 and OR3 emit light based on the application of voltage. Specifically, when a potential difference is formed between the lower electrode LE1 and the upper electrode UE1, the light emitting layer EML of the organic layer OR1 emits light in a blue wavelength range. When a potential difference is formed between the lower electrode LE2 and the upper electrode UE2, the light emitting layer EML of the organic layer OR2 emits light in a green wavelength range. When a potential difference is formed between the lower electrode LE3 and the upper electrode UE3, the light emitting layer EML of the organic layer OR3 emits light in a red wavelength range.

As another example, the light emitting layers EML of the organic layers OR1, OR2 and OR3 may emit light exhibiting the same color (for example, white). In this case, the display device DSP may comprise color filters which convert the light emitted from the light emitting layers EML into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers EML.

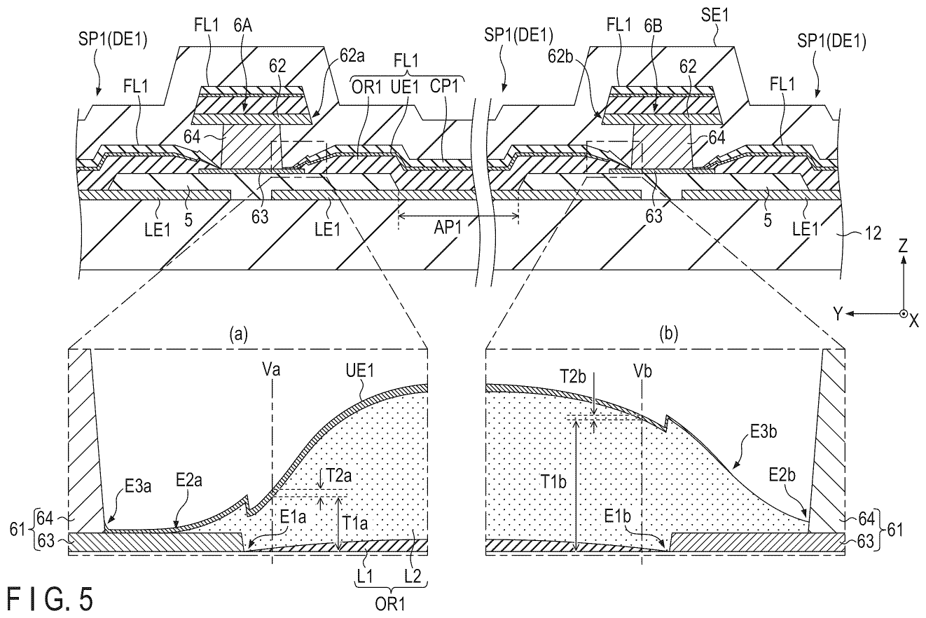

FIG. 5 is a schematic cross-sectional view of the display device DSP along the V-V line of FIG. 2. In this figure, the section corresponds to a Y-Z section defined by the Y-direction and the Z-direction and shows three subpixels SP1 arranged in the Y-direction. It should be noted that the substrate 10, the circuit layer 11, the resin layer 13, the sealing layer 14 and the resin layer 15 are omitted. In the following explanation, the partition 6 located on the left side of FIG. 5 is referred to as a first partition 6A, and the partition 6 located on the right side is referred to as a second partition 6B. These partitions 6A and 6B are provided such that the pixel aperture AP1 located in the middle of FIG. 5 is interposed between them in the Y-direction.

In the example of FIG. 5, the stacked film FL1 and the sealing layer SE1 are continuous on the partitions 6A and 6B. In other words, the sealing layer SE1 continuously covers the partitions 6A and 6B and the cap layer CP1 of each subpixel SP1.

As shown in the enlarged views (a) and (b) of FIG. 5, the organic layer OR1 has a first layer L1 and a second layer L2 provided on the first layer L1. This embodiment assumes the following case. The first layer L1 consists of a hole injection layer HIL, and the second layer L2 consists of a hole transport layer HTL, an electron blocking layer EBL, a light emitting layer EML, a hole blocking layer HBL, an electron transport layer ETL and an electron injection layer EIL. It should be noted that the first layer L1 may further include another layer such as a hole transport layer HTL in addition to the hole injection layer HIL. In FIG. 5 (a) and FIG. 5 (b), the cap layer CP1 and the sealing layer SE1 are omitted.

The thicknesses of the first layer L1 and the second layer L2 decrease toward the partitions 6A and 6B. Similarly, the thickness of the upper electrode UE1 decreases toward the partitions 6A and 6B.

The first layer L1 has an end portion Ela located on the first partition 6A side, and an end portion E1b located on the second partition 6B side. To prevent the generation of leak current between the organic layer OR1 and the partitions 6A and 6B, it is preferable that the hole injection layer HIL forming the first layer L1 should not be electrically connected to the partition 6. In other words, as shown in FIG. 5, the end portions Ela and E1b should be preferably spaced apart from the bottom layers 63 of the partitions 6A and 6B, respectively. However, the first layer L1 may be slightly in contact with at least one of these bottom layers 63.

The second layer L2 has an end portion E2a located on the first partition 6A side, and an end portion E2b located on the second partition 6B side. In the example of FIG. 5 (a) and FIG. 5 (b), the end portions E2a and E2b are located on the bottom layers 63 of the partitions 6A and 6B, respectively. In other words, the second layer L2 is in contact with the bottom layers 63 of the partitions 6A and 6B. As another example, the second layer L2 may not be in contact with the bottom layer 63 of the first partition 6A. Further, the second layer L2 may be in contact with neither the bottom layer 63 of the partition 6A nor the bottom layer 63 of the partition 6B.

As shown in FIG. 5 (a), the end portion E2a is spaced apart from the stem layer 64 of the first partition 6A. By this structure, an area which is not covered with the second layer L2 is formed on the upper surface of the bottom layer 63 of the first partition 6A. To the contrary, in the example of FIG. 5 (b), the end portion E2b is in contact with the stem layer 64 of the second partition 6B. By this structure, the upper surface of the bottom layer 63 of the second partition 6B is entirely covered with the second layer L2. As another example, the end portion E2b may be spaced apart from the stem layer 64 of the second partition 6B.

The upper electrode UE1 has an end portion E3a located on the first partition 6A side, and an end portion E3b located on the second partition 6B side. In the example of FIG. 5 (a), the end portion E3a is located on the bottom layer 63 of the first partition 6A and is further in contact with the stem layer 64. It should be noted that the end portion E3a may be spaced apart from the stem layer 64. To the contrary, in the example of FIG. 5 (b), the end portion E3b is located on the second layer L2 and is not in contact with the bottom layer 63 or the stem layer 64 of the second partition 6B. As another example, the end portion E3b may be in contact with the stem layer 64 of the second partition 6B.

Line segment Va shown by the chained line in FIG. 5 (a) is a straight line which passes through the first end portion 62a of the upper portion 62 of the first partition 6A and is parallel to the Z-direction. Line segment Vb shown by the chained line in FIG. 5 (b) is a straight line which passes through the second end portion 62b of the upper portion 62 of the second partition 6B and is parallel to the Z-direction.

The organic layer OR1 has thickness T1a at the position intersecting with line segment Va, that is, immediately under the first end portion 62a. The organic layer OR1 has thickness T1b at the position intersecting with line segment Vb, that is, immediately under the second end portion 62b. Each of thicknesses T1a and T1b corresponds to the total thickness of the first layer L1 and the second layer L2.

The upper electrode UE1 has thickness T2a at the position intersecting with line segment Va, that is, immediately under the first end portion 62a. The upper electrode UE1 has thickness T2b at the position intersecting with line segment Vb, that is, immediately under the second end portion 62b. For example, thickness T2a is less than thickness T1a (T2a<T1a). Thickness T2b is less than thickness T1b (T2b<T1b).

In the embodiment, thickness T1a is less than thickness T1b (T1a<T1b). Further, thickness T2a is greater than thickness T2b (T2a>T2b). Thus, the organic layer OR1 is formed so as to be thin near the first partition 6A and thick near the second partition 6B. The upper electrode UE1 is formed so as to be thick near the first partition 6A and thin near the second partition 6B.

In the embodiment, the contact area of the lower portion 61 (the bottom layer 63 and the stem layer 64) of the first partition 6A and the organic layer OR1 is less than that of the lower portion 61 of the second partition 6B and the organic layer OR1.

Further, the contact area of the lower portion 61 of the first partition 6A and the upper electrode UE1 is greater than that of the lower portion 61 of the second partition 6B and the upper electrode UE1. In the example of FIG. 5 (b), the upper electrode UE1 is not in contact with the lower portion 61 of the second partition 6B. In this case, the contact area of the lower portion 61 of the second partition 6B and the upper electrode UE1 is zero. The configuration is not limited to this example. The contact area may not be zero as the upper electrode UE1 is in contact with the bottom layer 63 and stem layer 64 of the second partition 6B.

Thus, in the example of FIG. 5, the contact area of the bottom layer 63 of the first partition 6A and the upper electrode UE1 is made large by forming the organic layer OR1 so as to be thin and further forming the upper electrode UE1 so as to be thick near the first partition 6A. By this configuration, the upper electrode UE1 can be satisfactorily electrically connected to the partition 6.

It should be noted that each subpixel SP1 provided in the display area DA has the same shape as subpixel SP1 shown in the middle of FIG. 5. Specifically, when each of the partitions 6A and 6B is particularly looked at, the vicinity of a side surface of the lower portion 61 comprises the structure of FIG. 5 (a), and the vicinity of the other side surface comprises the structure of FIG. 5 (b).

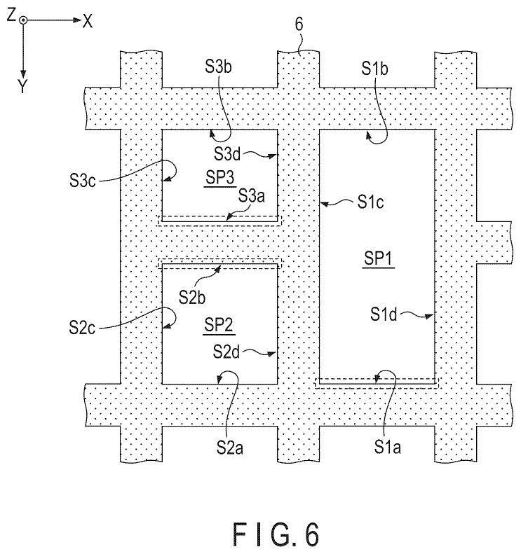

FIG. 6 is a schematic plan view of the partition 6 which surrounds subpixels SP1, SP2 and SP3. As shown in the figure, the four sides of the partition 6 which surrounds subpixel SP1 are defined as sides S1a, S1b, S1c and S1d. The four sides of the partition 6 which surrounds subpixel SP2 are defined as sides S2a, S2b, S2c and S2d. The four sides of the partition 6 which surrounds subpixel SP3 are defined as sides S3a, S3b, S3c and S3d. The sides S1a, S1b, S2a, S2b, S3a and S3b are parallel to the X-direction. The sides S1c, S1d, S2c, S2d, S3c and S3d are parallel to the Y-direction.

The sides S1a, S2b and S3a surrounded by the chained frames correspond to contact sides on which the respective upper electrodes UE1, UE2 and UE3 are in contact with the partition 6. Common voltage is applied to the upper electrodes UE1, UE2 and UE3 through at least these contact sides.

The structure of the side S1a is as shown in FIG. 5 (a). The structure of the organic layer OR2, the upper electrode UE2 and the partition 6 in the side S2b is similar to that of the organic layer OR1, the upper electrode UE1 and the first partition 6A shown in FIG. 5 (a). Further, the structure of the organic layer OR3, the upper electrode UE3 and the partition 6 in the side S3a is similar to that of the organic layer OR1, the upper electrode UE1 and the first partition 6A shown in FIG. 5 (a). By this configuration, the upper electrodes UE2 and UE3 can be satisfactorily electrically connected to the partition 6 in a manner similar to that of the upper electrode UE1.

The structure of the side S1b is as shown in FIG. 5 (b). The structure of the organic layer OR2, the upper electrode UE2 and the partition 6 in the side S2a is similar to that of the organic layer OR1, the upper electrode UE1 and the second partition 6B shown in FIG. 5 (b). Further, the structure of the organic layer OR3, the upper electrode UE3 and the partition 6 in the side S3b is similar to that of the organic layer OR1, the upper electrode UE1 and the second partition 6B shown in FIG. 5 (b).

It should be noted that the upper electrodes UE1, UE2 and UE3 may be in contact with the lower portion 61 in other sides in addition to the contact sides shown in the figure. In addition, the position of the contact side of subpixel SP1, SP2 or SP3 is not limited to the example of FIG. 6 and may be appropriately modified.

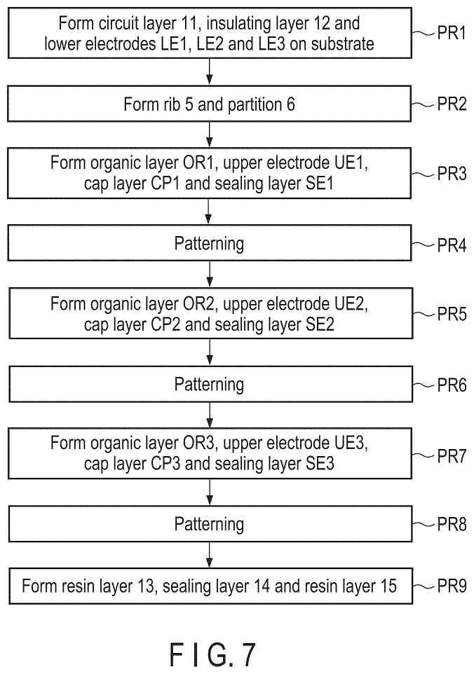

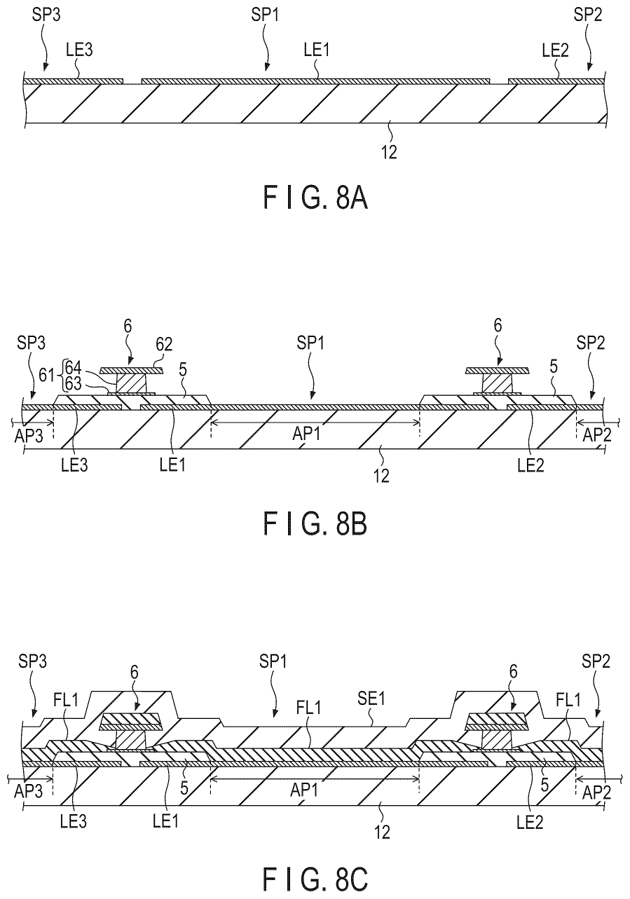

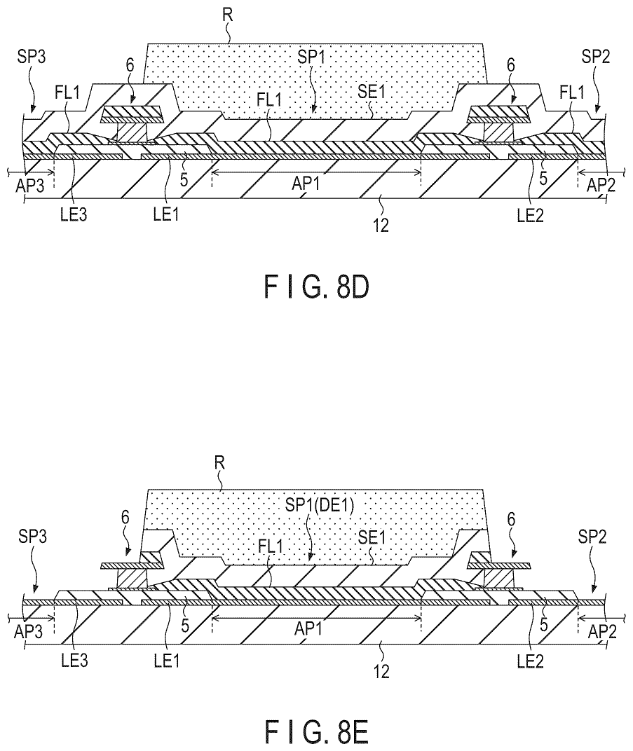

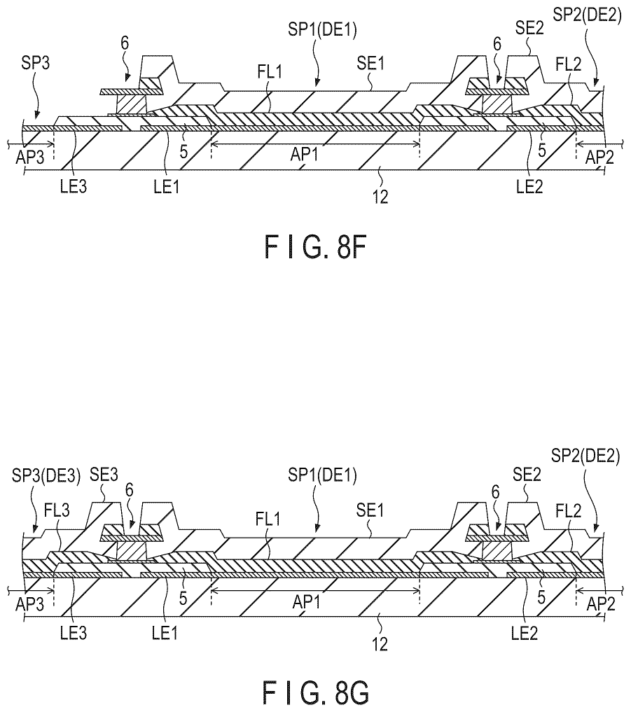

FIG. 7 is a flowchart showing an example of the manufacturing method of the display device DSP. Each of FIG. 8A to FIG. 8G is a schematic cross-sectional view showing the manufacturing process of the display device DSP. In FIG. 8A to FIG. 8G, the illustrations of the substrate 10 and the circuit layer 11 are omitted.

To manufacture the display device DSP, first, the circuit layer 11 and the organic insulating layer 12 are formed on the substrate 10, and further, the lower electrodes LE1, LE2 and LE3 are formed on the organic insulating layer 12 as shown in FIG. 8A (process PR1).

Subsequently, the rib 5 and the partition 6 are formed as shown in FIG. 8B (process PR2). The pixel apertures AP1, AP2 and AP3 of the rib 5 may be provided after the formation of the partition 6 or may be provided before the formation of the partition 6.

After preparing the substrate on which the lower electrodes LE1, LE2 and LE3, the rib 5 and the partition 6 are formed by processes PR1 and PR2, a process for forming the display elements DE1, DE2 and DE3 is performed. In the embodiment, this specification assumes a case where the display element DE1 is formed firstly, and the display element DE2 is formed secondly, and the display element DE3 is formed lastly. It should be noted that the formation order of the display elements DE1, DE2 and DE3 is not limited to this example.

To form the display element DE1, first, as shown in FIG. 8C, the stacked film FL1 and the sealing layer SE1 are formed (process PR3). The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1. The organic layer OR1, the upper electrode UE1 and the cap layer CP1 are formed by vapor deposition. The sealing layer SE1 is formed by chemical vapor deposition (CVD). The stacked film FL1 is divided into a plurality of portions by the partition 6 having an overhang shape.

After process PR3, the stacked film FL1 and the sealing layer SE1 are patterned (process PR4). In this patterning, as shown in FIG. 8D, a resist R is provided on the sealing layer SE1. The resist R covers subpixel SP1 and part of the partition 6 around the subpixel.

Subsequently, as shown in FIG. 8E, the portions of the stacked film FL1 and the sealing layer SE1 exposed from the resist R are removed by etching using the resist R as a mask. In other words, of the stacked film FL1 and the sealing layer SE1, the portions which overlap the lower electrode LE1 remain, and the other portions are removed. By this process, the display element DE1 is formed in subpixel SP1. For example, this etching includes wet etching and dry etching processes which are performed in order for the sealing layer SE1, the cap layer CP1, the upper electrode UE1 and the organic layer OR1. After these etching processes, the resist R is removed.

The display element DE2 is formed by a procedure similar to that of the display element DE1. Specifically, when the display element DE2 is formed, the stacked film FL2 and the sealing layer SE2 are formed in the entire display area DA (process PR5). The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2.

The organic layer OR2, the upper electrode UE2 and the cap layer CP2 are formed by vapor deposition. The sealing layer SE2 is formed by CVD. The stacked film FL2 is divided into a plurality of portions by the partition 6 having an overhang shape. The sealing layer SE2 continuously covers the portions into which the stacked film FL2 is divided, and the partition 6.

After process PR5, the stacked film FL2 and the sealing layer SE2 are patterned (process PR6). By this process, the display element DE2 is formed in subpixel SP2 as shown in FIG. 8F.

The display element DE3 is formed by a procedure similar to the procedures of the display elements DE1 and DE2. Specifically, when the display element DE3 is formed, the stacked film FL3 and the sealing layer SE3 are formed in the entire display area DA (process PR7). The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3.

The organic layer OR3, the upper electrode UE3 and the cap layer CP3 are formed by vapor deposition. The sealing layer SE3 is formed by CVD. The stacked film FL3 is divided into a plurality of portions by the partition 6 having an overhang shape. The sealing layer SE3 continuously covers the portions into which the stacked film FL3 is divided, and the partition 6.

After process PR7, the stacked film FL3 and the sealing layer SE3 are patterned (process PR8). By this process, the display element DE3 is formed in subpixel SP3 as shown in FIG. 8G.

After the display elements DE1, DE2 and DE3 are formed, the resin layer 13, sealing layer 14 and resin layer 15 shown in FIG. 3 are formed in order (process PR9). The display device DSP is completed through this process.

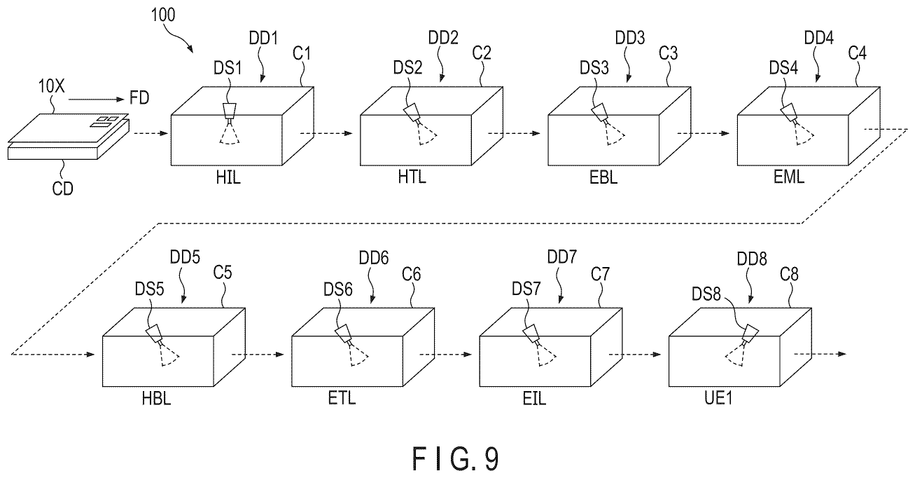

FIG. 9 is a diagram showing the schematic configuration of part of the manufacturing equipment 100 of the display device DSP. The manufacturing equipment 100 shown in the figure corresponds to a manufacturing line which forms the organic layer OR1 and the upper electrode UE1, and comprises evaporation devices DD1 to DD7 for forming the hole injection layer HIL, the hole transport layer HTL, the electron blocking layer EBL, the light emitting layer EML, the hole blocking layer HBL, the electron transport layer ETL and the electron injection layer EIL. The evaporation devices DD1 to DD7 constitute a first evaporation device for forming the organic layer OR1. The manufacturing equipment 100 further comprises an evaporation device DD8 (second evaporation device) for forming the upper electrode UE1.

The evaporation devices DD1 to DD8 comprise chambers C1 to C8 provided such that the inside is maintained as a vacuum, respectively, and evaporation sources DS1 to DS8 provided inside the chambers C1 to C8, respectively. Further, the manufacturing equipment 100 comprises a conveyance device CD which conveys a substrate 10X on which the partition 6 is formed through process PR2. The substrate 10X may be a mother substrate on which a plurality of panel portions each corresponding to the display device DSP are formed. The conveyance device CD conveys the substrate 10X to the chambers C1 to C8 in series. In the following explanation, the direction in which the substrate 10X passes through the chambers C1 to C8 (the direction in which the substrate 10X relatively moves with respect to the evaporation sources DS1 to DS8) is referred to as a moving direction FD.

It should be noted that FIG. 9 shows an example in which the manufacturing equipment 100 comprises the evaporation devices DD1 to DD7 by assuming a case where the organic layer OR1 comprises a configuration in which the hole injection layer HIL, the hole transport layer HTL, the electron blocking layer EBL, the light emitting layer EML, the hole blocking layer HBL, the electron transport layer ETL and the electron injection layer EIL are stacked in order. However, the configuration of the evaporation devices provided in the manufacturing equipment 100 could be modified based on the configuration of the thin films included in the organic layer OR1.

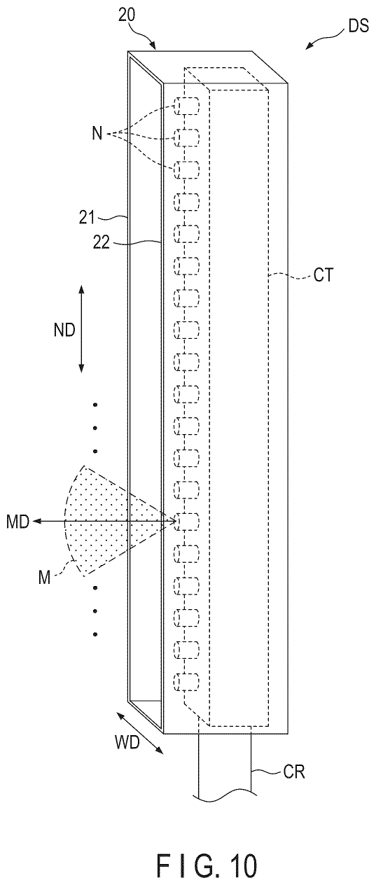

FIG. 10 is a schematic perspective view of an evaporation source DS which can be applied to the evaporation sources DS1 to DS8. The evaporation source DS comprises a crucible CR, a long container CT connected to the crucible CR, and a plurality of nozzles N provided in the container CT. The nozzles N are linearly arranged on a surface of the container CT. In the following explanation, the direction in which the nozzles N are arranged is called a nozzle alignment direction ND. A direction orthogonal to the nozzle alignment direction ND is called a width direction WD.

The crucible CR vaporizes (volatilizes or sublimates) the material accommodated in the crucible CR by heating the material. The vaporized material M is supplied to the container CT and is emitted from each nozzle N.

In the following explanation, the direction in which the material M is emitted from each nozzle N is called evaporation direction MD. Evaporation direction MD is, for example, parallel to the axis of each nozzle N (the extension direction of each nozzle N) and is orthogonal to the nozzle alignment direction ND and the width direction WD in the example of FIG. 10. The material M is emitted from each nozzle N with a predetermined spread angle based on evaporation direction MD. Evaporation direction MD can be also regarded as a direction parallel to the central axis of the material M emitted from each nozzle N, or the main emission direction of the material M.

The evaporation source DS may further comprise a shield 20 which surrounds the nozzles N. In the example of FIG. 10, the shield 20 surrounds the container CT and the nozzles N and has a shape in which the nozzle N side is open.

The shield 20 has a first sidewall 21 and a second sidewall 22 in the width direction WD. These sidewalls 21 and 22 protrude relative to the distal end of each nozzle N in evaporation direction MD and prevent the material M from spreading in the width direction WD.

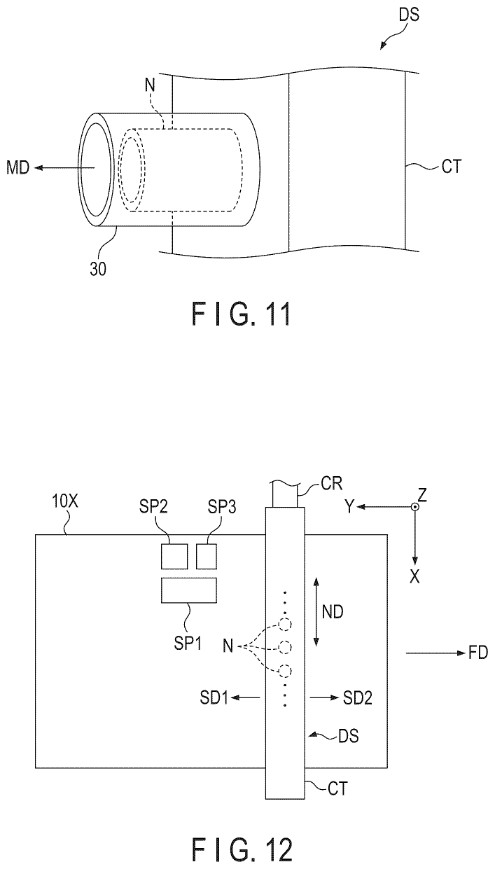

FIG. 11 is a schematic perspective view showing another example which can be applied to the evaporation source DS. In the example of this figure, a shield 30 is further provided relative to the nozzle N. The shield 30 has, for example, a cylindrical shape which surrounds the nozzle N, and is attached to the container CT. The shield 30 protrudes in evaporation direction MD relative to the distal end of the nozzle N. This configuration prevents the material M emitted from the nozzle N from spreading in all directions based on the nozzle N.

FIG. 12 is a schematic plan view showing an example of the relationship between the substrate 10X which is conveyed and the evaporation source DS. In the example of FIG. 12, the moving direction FD of the substrate 10X is parallel to the Y-direction. The moving direction FD and the nozzle alignment direction ND are orthogonal to each other. Each nozzle N emits the material M vaporized in the crucible CR and supplied to the container CT toward the substrate 10X which relatively moves in the moving direction FD with respect to the evaporation source DS. In the following explanation, the upstream side of the moving direction FD viewed from the evaporation source DS is called a first lateral direction SD1, and the downstream side is called a second lateral direction SD2.

This relationship between the substrate 10X and the evaporation source DS can be applied to all of the evaporation devices DD1 to DD8 shown in FIG. 9. In the manufacturing equipment 100, the configuration of a manufacturing line which forms the organic layer OR2 and the upper electrode UE2 and the configuration of a manufacturing line which forms the organic layer OR3 and the upper electrode UE3 are similar to the configuration explained with reference to FIG. 9 to FIG. 12.

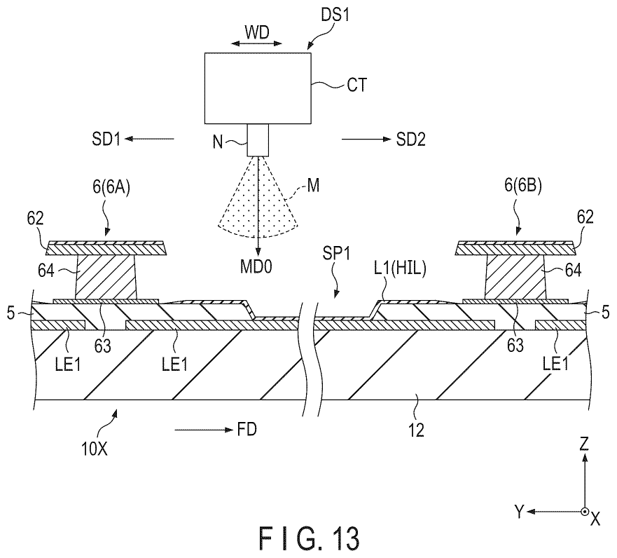

FIG. 13 is a schematic cross-sectional view showing the process of forming the hole injection layer HIL by the evaporation source DS1. The section shown in this figure corresponds to a Y-Z section similar to that of FIG. 5. In the example of FIG. 13, evaporation direction MD0 of the evaporation source DS1 is parallel to the Z-direction (the normal direction of the substrate 10X). Thus, the evaporation source DS1 does not incline with respect to the Z-direction.

As described above, the hole injection layer HIL should be preferably spaced apart from the bottom layer 63 of the partition 6. To reduce the spread of the material M emitted from each nozzle N, the evaporation source DS1 should preferably comprise the shield 30 shown in FIG. 11. The evaporation source DS1 may further comprise the shield 20 shown in FIG. 10. When the spread of the material M is reduced, the material M is blocked by the upper portion 62 of the partition 6, and the material M is not easily attached to the lower side of the upper portion 62. This configuration can prevent the contact between the hole injection layer HIL (first layer L1) and the lower portion 61 (the bottom layer 63 and the stem layer 64).

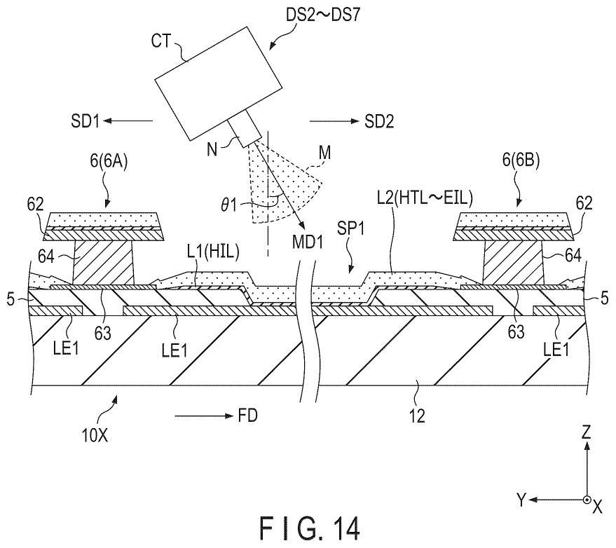

FIG. 14 is a schematic cross-sectional view showing the process of forming the hole transport layer HTL, the electron blocking layer EBL, the light emitting layer EML, the hole blocking layer HBL, the electron transport layer ETL and the electron injection layer EIL by the evaporation sources DS2 to DS7. The section shown in this figure corresponds to a Y-Z section similar to that of FIG. 13.

Evaporation direction MD1 of the evaporation sources DS2 to DS7 inclines to the second lateral direction SD2 relative to the Z-direction. Evaporation direction MD1 forms angle θ1 which is an acute angle with the Z-direction. Each of the evaporation sources DS2 to DS7 may comprise at least one of the shields 20 and 30 described above.

In the example of FIG. 14, the evaporation sources DS2 to DS7 including the container CT and the nozzles N entirely incline with respect to the Z-direction. As another example, the extension direction of each nozzle N may be inclined without inclining the container CT.

When evaporation direction MD1 of the evaporation sources DS2 to DS7 inclines as shown in FIG. 14, the material M is easily attached to the vicinity of, of the pair of side surfaces of each partition 6, the side surface located on the upstream side of the moving direction FD, and the material M is not easily attached to the vicinity of the side surface located on the downstream side. Thus, the second layer L2 whose thickness differs between the vicinities of the partitions 6A and 6B can be formed as shown in FIG. 5.

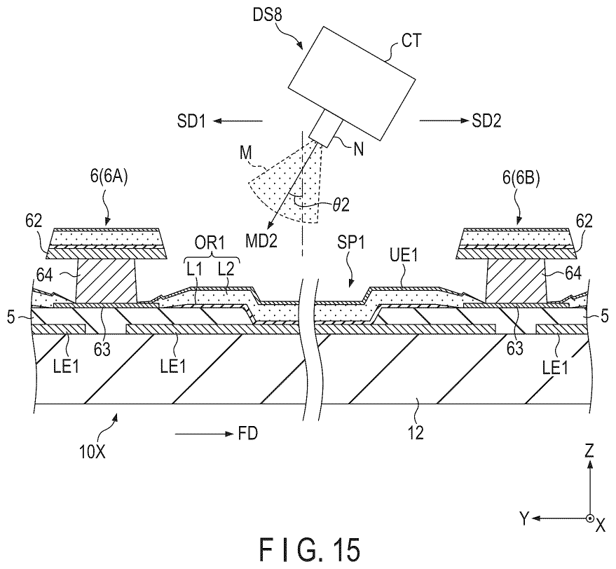

FIG. 15 is a schematic cross-sectional view showing the process of forming the upper electrode UE1 by the evaporation source DS8. The section shown in this figure corresponds to a Y-Z section similar to the sections of FIG. 13 and FIG. 14.

Evaporation direction MD2 of the evaporation source DS8 inclines to the first lateral direction SD1 relative to the Z-direction. Thus, evaporation direction MD2 inclines to the opposite direction of evaporation direction MD1. Evaporation direction MD2 forms angle θ2 which is an acute angle with the Z-direction. Angle θ2 may be equal to angle θ1 or may be different from angle θ1. The evaporation source DS8 may comprise at least one of the shields 20 and 30 described above.

In the example of FIG. 15, the evaporation source DS8 including the container CT and the nozzles N entirely inclines with respect to the Z-direction. As another example, the extension direction of each nozzle N may be inclined without inclining the container CT.

When evaporation direction MD2 of the evaporation source DS8 inclines as shown in FIG. 15, the material M is not easily attached to the vicinity of, of the pair of side surfaces of each partition 6, the side surface located on the upstream side of the moving direction FD, and the material M is easily attached to the vicinity of the side surface located on the downstream side. Thus, the upper electrode UE1 whose thickness differs between the vicinities of the partitions 6A and 6B can be formed as shown in FIG. 5.

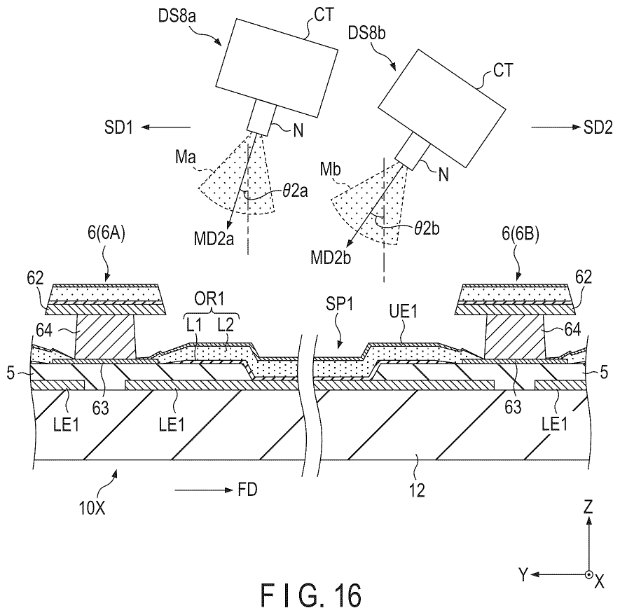

FIG. 16 is a schematic cross-sectional view showing another example of the process of forming the upper electrode UE1. When the upper electrode UE1 is formed of an alloy of magnesium and silver as described above, the upper electrode UE1 is formed by co-evaporation of magnesium and silver.

Specifically, an evaporation source DS8a which emits material Ma which is magnesium and an evaporation source DS8b which emits material Mb which is silver are provided in the chamber C8 (see FIG. 9) of the evaporation device DD8. For example, these evaporation sources DS8a and DS8b are provided so as to be close to each other in the moving direction FD.

In the example of FIG. 16, both evaporation direction MD2a of the evaporation source DS8a and evaporation direction MD2b of the evaporation source DS8b incline to the first lateral direction SD1 relative to the Z-direction. Evaporation direction MD2a forms angle θ2a with the Z-direction, and evaporation direction MD2b forms angle θ2b with the Z-direction. Each of angles θ2a and 02b is an acute angle.

The area to which the evaporation source DS8a emits material Ma and the area to which the evaporation source DS8b emits material Mb should preferably overlap each other on the surface of the substrate 10X. For this reason, in the example of FIG. 16, evaporation directions MD2a and MD2b incline such that angle θ2b is greater than angle θ2a.

When the upper electrode UE1 is formed by co-evaporation of two types of conductive materials, a conductive material having a high co-evaporation ratio (film-thickness ratio) should be preferably emitted from the evaporation source DS8b having a great inclination. By this configuration, a thick conductive material easily goes into the lower side of the upper portion 62 of the partition 6. Thus, the upper electrode UE1 can be formed so as to be thick immediately under the upper portion 62. As a result, the upper electrode UE1 and the partition 6 are easily electrically connected to each other.

For example, the co-evaporation ratio between magnesium (first conductive material) and silver (second conductive material) constituting the upper electrode UE1 is Mg:Ag=2:8. In this case, like the example described above, magnesium should be preferably emitted from the evaporation source DS8a, and silver should be preferably emitted from the evaporation source DS8b. By this configuration, the upper electrode UE1 can be formed so as to be thick immediately under the upper portion 62 of the partition 6A with which the upper electrode UE1 should be in contact.

FIG. 9, FIG. 10 and FIG. 14 show the state in which each thin film of the organic layer OR1 is formed by one evaporation source. However, among the thin films constituting the organic layer OR1, for example, the hole injection layer HIL, the light emitting layer EML and the electron transport layer ETL could be formed by co-evaporation of a host material and a dopant. Regarding an evaporation device which forms each of these thin films, in a manner similar to that of the example of FIG. 16, a plurality of evaporation sources in which the inclinations of the evaporation direction differ from each other may be provided in the chamber.

When the organic layers OR2 and OR3 and the upper electrodes UE2 and UE3 are formed, in a manner similar to that of the examples shown in FIG. 13 to FIG. 16, evaporation direction MD0 of the hole injection layer HIL should be parallel to the Z-direction. Further, evaporation direction MD1 of the hole transport layer HTL, the electron blocking layer EBL, the light emitting layer EML, the hole blocking layer HBL, the electron transport layer ETL and the electron injection layer EIL and evaporation direction MD2 of the upper electrodes UE2 and UE3 should incline to opposite directions.

However, when the sides S1a, S2b and S3a are set as the contact sides of subpixels SP1, SP2 and SP3, respectively, as shown in FIG. 6, evaporation directions MD1 and MD2 applied at the time of forming the organic layer OR2 and the upper electrode UE2 incline to the opposite directions of evaporation directions MD1 and MD2 applied at the time of forming the organic layer OR1 and the upper electrode UE1, respectively. By this configuration, near the side S2b, the thickness of the organic layer OR2 can be reduced, and further, the thickness of the upper electrode UE2 can be increased.

When the manufacturing method of the embodiment is used, as exemplarily shown in the structure of FIG. 5, near the contact sides, the organic layers OR1, OR2 and OR3 can be made thin, and further, the upper electrodes UE1, UE2 and UE3 can be made thick. In this manner, as explained using FIG. 5 and FIG. 6, the upper electrodes UE1, UE2 and UE3 can be satisfactorily electrically connected to the partition 6 in the contact sides.

It should be noted that the hole transport layer HTL, the electron blocking layer EBL, the light emitting layer EML, the hole blocking layer HBL, the electron transport layer ETL and the electron injection layer EIL are examples of a first thin film formed by inclining the evaporation direction in the manufacturing method exemplarily shown in FIG. 9 to FIG. 16. Further, the hole injection layer HIL is an example of a second thin film formed without inclining the evaporation direction.

As another example, the evaporation directions of all of the thin films constituting the organic layer OR1 including the hole injection layer HIL may incline with respect to the Z-direction in a manner similar to that of evaporation direction MD1 shown in FIG. 14. At least one of the evaporation directions of the hole transport layer HTL, the electron blocking layer EBL, the light emitting layer EML, the hole blocking layer HBL, the electron transport layer ETL and the electron injection layer EIL may not incline with respect to the Z-direction.

Thus, at least one of the evaporation directions of the thin films constituting the organic layer OR1 should incline to the opposite direction of the evaporation direction of the upper electrode UE1. By this configuration, the organic layer OR1 is made thin in the contact side in which the upper electrode UE1 is formed so as to be thick. Therefore, the conduction between the upper electrode UE1 and the partition 6 is improved compared to a case where all of the evaporation directions MD of the thin films are parallel to the Z-direction.

At least one of the evaporation directions of the thin films constituting the organic layer OR1 may be inclined to the same direction as the evaporation direction of the upper electrode UE1 at an angle less than the evaporation direction of the upper electrode UE1. In this case, similarly, the upper electrode UE1 can be formed so as to be closer to the lower portion 61 than the organic layer OR1 in the contact side.

In the manufacturing method exemplarily shown in FIG. 9 to FIG. 16, this specification exemplarily shows the configuration in which the substrate 10X relatively moves with respect to the still evaporation sources DS1 to DS8 as the substrate 10X is conveyed in the moving direction FD by the conveyance device CD. As another example, when the evaporation sources DS1 to DS8 perform vapor deposition, the substrate 10X may stand still in each of the chambers C1 to C8, and the evaporation sources DS1 to DS8 may relatively move with respect to this substrate 10X. In this case, for example, the evaporation devices DD1 to DD8 comprise respective driving mechanisms for moving the respective evaporation sources DS1 to DS8 in the respective chambers C1 to C8.

The modified examples described above regarding the organic layer OR1 and the upper electrode UE1 can be applied to the organic layers OR2 and OR3 and the upper electrodes UE2 and UE3 in a similar manner.

The configuration of the partition 6 is not limited to FIG. 5 etc. Several modified examples which could be applied to the partition 6 are shown below.

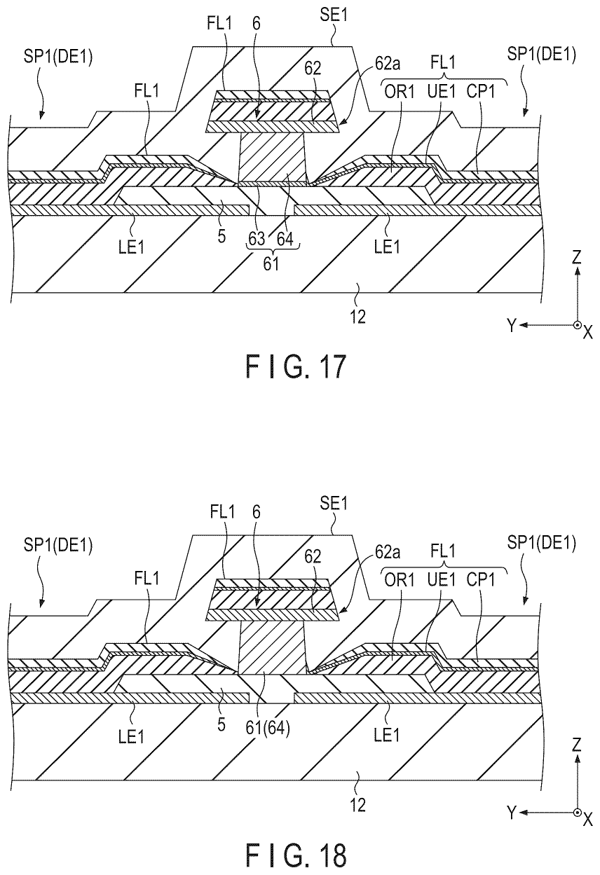

FIG. 17 is a schematic cross-sectional view showing the first modified example of a configuration which could be applied to the partition 6. In the example of this figure, the both end portions of the bottom layer 63 are aligned with the side surfaces of the stem layer 64. The right side surface of the partition 6 shown in the figure corresponds to the contact side with the upper electrode UE1. Thus, the upper electrode UE1 of the right subpixel SP1 in the figure is in contact with the side surfaces of the bottom layer 63 and the stem layer 64. To the contrary, the organic layer OR1 of the right subpixel SP1 is spaced apart from the side surfaces of the bottom layer 63 and the stem layer 64. As another example, this organic layer OR1 may be in contact with the side surfaces of the bottom layer 63 and the stem layer 64.

FIG. 18 is a schematic cross-sectional view showing the second modified example of a configuration which could be applied to the partition 6. In the example of this figure, the lower portion 61 does not comprise the bottom layer 63. Thus, the lower portion 61 consists of the stem layer 64. In this figure, similarly, the right side surface of the partition 6 corresponds to the contact side, and the upper electrode UE1 is in contact with this side surface. In a manner similar to that of the example of FIG. 17, the organic layer OR1 of the right subpixel SP1 is spaced apart from the side surface of the stem layer 64. As another example, this organic layer OR1 may be in contact with the side surface of the stem layer 64.

### Second Embodiment

A second embodiment is explained. This embodiment discloses other configurations which could be applied to the evaporation sources DS2 to DS7 shown in FIG. 9. The configuration of a display device DSP and the manufacturing process other than the vapor deposition using the evaporation sources DS2 to DS7 are similar to those disclosed in the first embodiment.

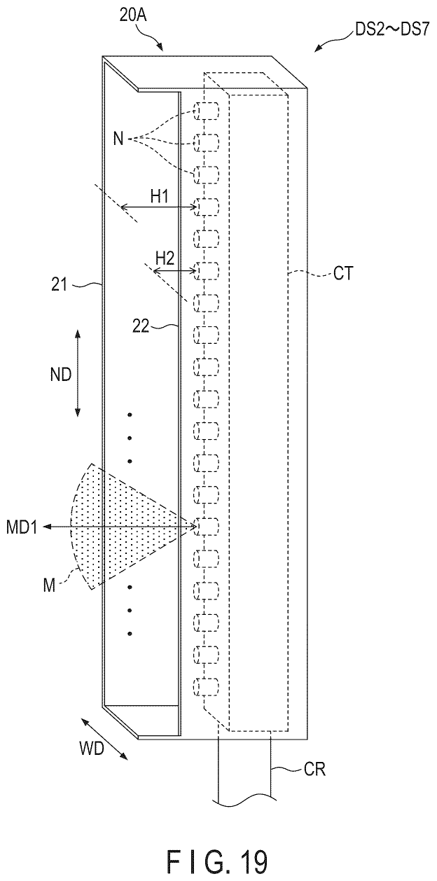

FIG. 19 is a schematic perspective view showing an example of a configuration which can be applied to the evaporation sources DS2 to DS7 according to this embodiment. In a manner similar to that of the evaporation source DS shown in FIG. 10, each of the evaporation sources DS2 to DS7 comprises a crucible CR, a container CT and a plurality of nozzles N. Further, each of the evaporation sources DS2 to DS7 comprises a shield 20A similar to the shield 20 shown in FIG. 10.

The shield 20A has a first sidewall 21 and a second sidewall 22 in the width direction WD. Each of the sidewalls 21 and 22 has, for example, a flat-plate shape parallel to the nozzle alignment direction ND and evaporation direction MD1. In the example of FIG. 19, the sidewalls 21 and 22 protrude in evaporation direction MD1 relative to the distal end of each nozzle N. Height H1 of the first sidewall 21 from the distal end of each nozzle N is greater than height H2 of the second sidewall 22 from the distal end of each nozzle N (H1>H2).

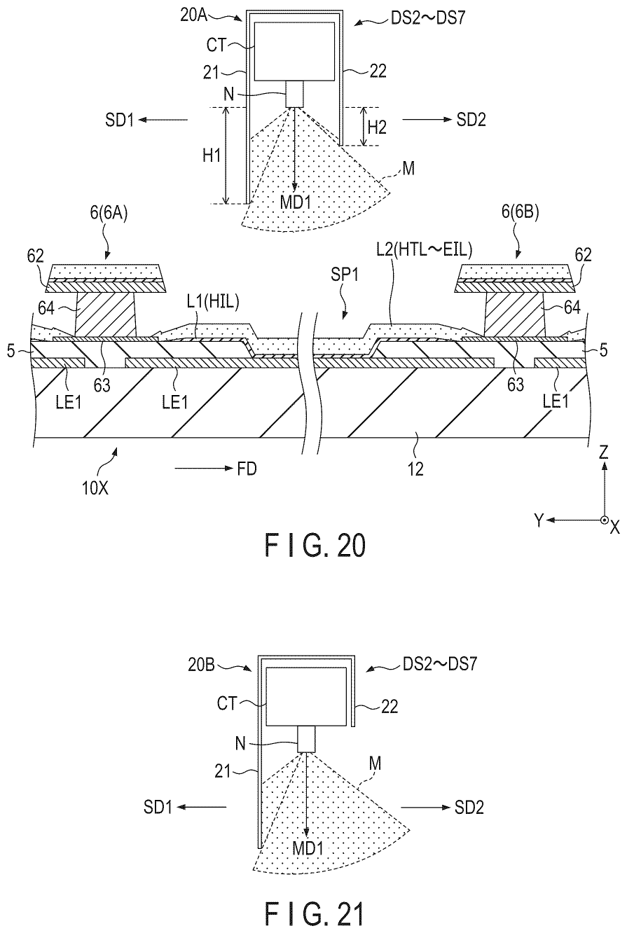

FIG. 20 is a schematic cross-sectional view showing the process of performing vapor deposition using the evaporation sources DS2 to DS7 shown in FIG. 19. The section shown in this figure corresponds to a Y-Z section similar to that of FIG. 14.

In the example of FIG. 20, evaporation direction MD1 of the evaporation sources DS2 to DS7 is parallel to a Z-direction. It should be noted that evaporation direction MD1 may incline with respect to the Z-direction in a manner similar to that of the example of FIG. 14.

In the example of FIG. 20, the first sidewall 21 of the shield 20A is located in a first lateral direction SD1 relative to the nozzles N. The second sidewall 22 of the shield 20A is located in a second lateral direction SD2 relative to the nozzles N.

The sidewalls 21 and 22 block part of the material M emitted from the nozzles N. Since height H1 is greater than height H2 as described above, in the example of FIG. 20, the first sidewall 21 blocks the material M in a broader range than the second sidewall 22. Thus, the material M which goes to a substrate 10X without being blocked by the shield 20A has a shape which inclines to the second lateral direction SD2 as a whole. By this configuration, in a manner similar to that of the example of FIG. 14, a second layer L2 whose thickness differs between the vicinities of partitions 6A and 6B can be formed.

FIG. 21 is a schematic cross-sectional view showing another configuration which can be applied to the evaporation sources DS2 to DS7. Each of the evaporation sources DS2 to DS7 shown in the example of this figure comprises a shield 20B. The shield 20B has a first sidewall 21 and a second sidewall 22 in a manner similar to that of the shield 20A. In the shield 20B, the second sidewall 22 does not protrude from the distal end of each nozzle N. In other words, the material M emitted from each nozzle N is not blocked in the second lateral direction SD2. Even if the shield 20B has this shape, the material M which goes to the substrate 10X without being blocked by the shield 20B has a shape which inclines to the second lateral direction SD2 as a whole.

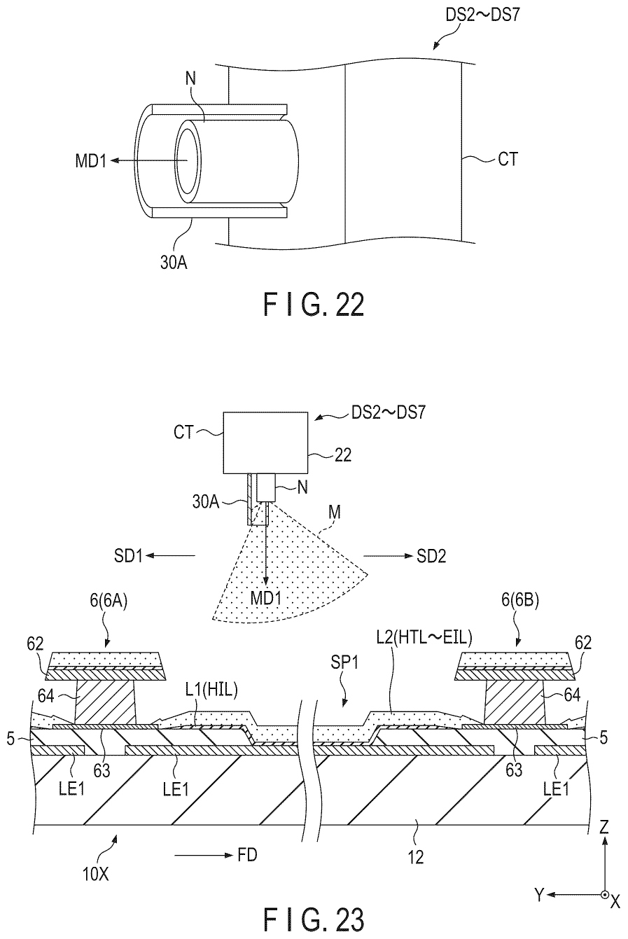

FIG. 22 is a schematic perspective view showing yet another configuration which can be applied to the evaporation sources DS2 to DS7. In the example of this figure, a shield 30A is provided near each nozzle N. The shield 30A has a half-cylindrical shape which surrounds part of the circumference of the nozzle N in a manner different from that of the shield 30 shown in FIG. 11.

FIG. 23 is a schematic cross-sectional view showing the process of performing vapor deposition using the evaporation sources DS2 to DS7 shown in FIG. 22. The section shown in this figure corresponds to a Y-Z section similar to that of FIG. 20.

In the example of FIG. 23, the shield 30A is located in the first lateral direction SD1 relative to the nozzles N. The shield 30A has, for example, the half-cylindrical shape shown in FIG. 22. However, a half portion which overlaps the nozzle N is omitted in FIG. 23. The shield 30A blocks part of the material M emitted from each nozzle N in a manner similar to that of the first sidewall 21 shown in FIG. 20. In the second lateral direction SD2, the material M is not blocked by the shield 30A. Thus, the material M which goes to the substrate 10X has a shape which inclines to the second lateral direction SD2 as a whole. By this configuration, in a manner similar to that of the example of FIG. 20, the second layer L2 whose thickness differs between the vicinities of the partitions 6A and 6B can be formed.

All of the shield 20A shown in FIG. 20, the shield 20B shown in FIG. 21 and the shield 30A shown in FIG. 23 have a shape in which the height on the first lateral direction SD1 side of each nozzle N is greater than the height on the second direction SD2 side of each nozzle N. The shield having this shape can be realized by various forms other than the forms shown in the drawings. Each of the evaporation sources DS2 to DS7 may comprise both one of the shields 20A and 20B and the shield 30A.

For example, the shield 30 shown in FIG. 11 is provided in the evaporation source DS1 for forming the hole injection layer HIL. The shield 30 surrounds the nozzle N and has a uniform height over the whole circumference of the nozzle N. In other words, for example, when the section is viewed in the same section as FIG. 23, the shield 30 has a shape in which the height on the first lateral direction SD1 side of each nozzle N is equal to the height on the second lateral direction SD2 side of each nozzle N. By using this shield 30, the range of the material M emitted from each nozzle N can be narrowed in all directions, and the hole injection layer HIL can be formed so as not to be in contact with the lower portion 61 of the partition 6.

As another example, one of the shields 20A, 20B and 30A may be provided in the evaporation source DS1 for forming the hole injection layer HIL. In this case, the evaporation sources DS1 to DS7 of all of the thin films constituting the organic layer OR1 comprise a shield having a shape in which the height on the first lateral direction SD1 side of each nozzle N is greater than the height on the second lateral direction SD2 side.

All of the display devices and the manufacturing methods and manufacturing equipment of the display devices that can be implemented by a person of ordinary skill in the art through arbitrary design changes to the display device and the manufacturing method and manufacturing equipment of the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

A display device and a manufacturing method and manufacturing equipment of a display device recognized from the embodiments described above are additionally described below.

(1) A display device comprising:
a substrate;
a lower electrode provided above the substrate;
a rib having a pixel aperture which overlaps the lower electrode;
a partition which has a conductive lower portion provided on the rib and an upper portion protruding from a side surface of the lower portion;
an organic layer which is in contact with the lower electrode through the pixel aperture and emits light based on application of voltage; and
an upper electrode which covers the organic layer and is in contact with the lower portion of the partition, wherein
the partition has first and second partitions which are provided such that the pixel aperture is interposed between the first and second partitions,
the upper portion of the first partition has a first end portion which overlaps the organic layer and the upper electrode,
the upper portion of the second partition has a second end portion which overlaps the organic layer and the upper electrode,
a thickness of the organic layer immediately under the first end portion is less than a thickness of the organic layer immediately under the second end portion, and
a thickness of the upper electrode immediately under the first end portion is greater than a thickness of the upper electrode immediately under the second end portion.

(2) The display device of the above (1), wherein
a contact area of the lower portion of the first partition and the organic layer is less than a contact area of the lower portion of the second partition and the organic layer.

(3) The display device of the above (2), wherein
a contact area of the lower portion of the first partition and the upper electrode is greater than a contact area of the lower portion of the second partition and the upper electrode.

(4) The display device of the above (1), wherein
the organic layer has a first layer and a second layer located on the first layer,
the first layer is spaced apart from the lower portions of the first and second partitions, and
the second layer is in contact with at least the lower portion of the second partition.

(5) The display device of the above (4), wherein
the first layer includes a hole injection layer, and
the second layer includes a light emitting layer.

(6) The display device of the above (1), further comprising a cap layer which covers the upper electrode.

(7) The display device of the above (6), further comprising a sealing layer which continuously covers the cap layer, the first partition and the second partition.

(8) The display device of one of the above (1) to (7), wherein
the lower portion includes:
   a conductive bottom layer provided on the rib; and
   a stem layer provided on the bottom layer, and
the upper electrode is in contact with at least the bottom layer of the lower portion of the first partition.

(9) The display device of the above (8), wherein
an end portion of the bottom layer protrudes from a side surface of the stem layer.

(10) A manufacturing method of a display device, including:
preparing a substrate including:
   a lower electrode;
   a rib having a pixel aperture which overlaps the lower electrode; and
   a partition which has a conductive lower portion provided on the rib and an upper portion protruding from a side surface of the lower portion;
forming an organic layer which is in contact with the lower electrode through the pixel aperture and emits light based on application of voltage by vapor deposition; and
forming an upper electrode which covers the organic layer and is in contact with the lower portion of the partition by vapor deposition, wherein
the organic layer includes a first thin film,
a first evaporation direction, in which a first evaporation source used to form the first thin film emits a vaporized material, inclines with respect to a normal direction of the substrate, and
a second evaporation direction, in which a second evaporation source used to form the upper electrode emits a vaporized material, inclines to an opposite direction of the first evaporation direction with respect to the normal direction.

(11) The manufacturing method of the above (10), wherein
the organic layer includes a second thin film, and
a third evaporation direction, in which a third evaporation source used to form the second thin film emits a vaporized material, is parallel to the normal direction.

(12) The manufacturing method of the above (11), wherein
the first thin film is one of a hole transport layer, an electron blocking layer, a light emitting layer, a hole blocking layer, an electron transport layer and an electron injection layer, and
the second thin film is a hole injection layer.

(13) The manufacturing method of the above (10), wherein
the organic layer consists of a plurality of thin films including the first thin film, and
in each of a plurality of evaporation sources used to form the thin films, an evaporation direction for emitting a vaporized material inclines to an opposite direction of the second evaporation direction with respect to the normal direction.

(14) The manufacturing method of one of the above (10) to (13), further including forming a cap layer which covers the upper electrode.

(15) The manufacturing method of the above [14], further including forming a sealing layer which continuously covers the cap layer and the partition.

(16) A manufacturing method of a display device, including:
preparing a substrate including:
   a lower electrode;
   a rib having a pixel aperture which overlaps the lower electrode; and
   a partition which has a conductive lower portion provided on the rib and an upper portion protruding from a side surface of the lower portion;
forming an organic layer which is in contact with the lower electrode through the pixel aperture and emits light based on application of voltage by vapor deposition; and
forming an upper electrode which covers the organic layer and is in contact with the lower portion of the partition by vapor deposition, wherein
the organic layer includes a first thin film,
a first evaporation source used to form the first thin film comprises a first nozzle which emits a vaporized material in a first evaporation direction, and a first shield which protrudes from the first nozzle,
a second evaporation source used to form the upper electrode comprises a second nozzle which emits a vaporized material in a second evaporation direction,
the second evaporation direction inclines to a first lateral direction with respect to a normal direction of the substrate, and
the first shield has a shape in which a height on a first lateral direction side of the first nozzle is greater than a height on a second lateral direction side opposite to the first lateral direction side.

(17) The manufacturing method of the above (16), wherein
the organic layer includes a second thin film,
a third evaporation source used to form the second thin film comprises a third nozzle which emits a vaporized material in a third evaporation direction, and a second shield which protrudes from the third nozzle, and
the second shield has a shape in which a height on a first lateral direction side of the third nozzle is equal to a height on a second lateral direction side of the third nozzle.

(18) The manufacturing method of the above (17), wherein
the second shield surrounds the third nozzle and has a uniform height over a whole circumference of the third nozzle.

(19) The manufacturing method of the above (17), wherein
the first thin film is one of a hole transport layer, an electron blocking layer, a light emitting layer, a hole blocking layer, an electron transport layer and an electron injection layer, and
the second thin film is a hole injection layer.

(20) The manufacturing method of the above (16), wherein
the organic layer consists of a plurality of thin films including the first thin film, and
each of a plurality of evaporation sources used to form the thin films comprises a nozzle which emits a vaporized material, and a shield having a shape in which a height on a first lateral direction side of the nozzle is greater than a height on a second lateral direction side.

(21) The manufacturing method of one of the above (16) to (20), further including forming a cap layer which covers the upper electrode.

(22) The manufacturing method of the above [21], further including forming a sealing layer which continuously covers the cap layer and the partition.

(23) Manufacturing equipment of a display device, comprising:
for a substrate including:
   a lower electrode;
   a rib having a pixel aperture which overlaps the lower electrode; and
   a partition which has a conductive lower portion provided on the rib and an upper portion protruding from a side surface of the lower portion,
a first evaporation device forming an organic layer which is in contact with the lower electrode through the pixel aperture and emits light based on application of voltage; and
a second evaporation device forming an upper electrode which covers the organic layer and is in contact with the lower portion of the partition for the substrate, wherein
the organic layer includes a first thin film,
the first evaporation device comprises a first evaporation source used to form the first thin film,
the second evaporation device comprises a second evaporation source used to form the upper electrode,
a first evaporation direction in which the first evaporation source emits a vaporized material inclines with respect to a normal direction of the substrate, and
a second evaporation direction in which the second evaporation source emits a vaporized material inclines to an opposite direction of the first evaporation direction with respect to the normal direction.

(24) The manufacturing equipment of the above (23), wherein
the organic layer includes a second thin film,
the first evaporation device comprises a third evaporation source used to form the second thin film, and
a third evaporation direction in which the third evaporation source emits a vaporized material is parallel to the normal direction.

(25) The manufacturing equipment of the above (24), wherein
the first thin film is one of a hole transport layer, an electron blocking layer, a light emitting layer, a hole blocking layer, an electron transport layer and an electron injection layer, and
the second thin film is a hole injection layer.

(26) The manufacturing equipment of the above (23), wherein
the organic layer consists of a plurality of thin films including the first thin film, and
in each of a plurality of evaporation sources used to form the thin films, an evaporation direction for emitting a vaporized material inclines to an opposite direction of the second evaporation direction with respect to the normal direction.

(27) A manufacturing equipment of a display device, comprising:
for a substrate including:
   a lower electrode;
   a rib having a pixel aperture which overlaps the lower electrode; and
   a partition which has a conductive lower portion provided on the rib and an upper portion protruding from a side surface of the lower portion,
a first evaporation device forming an organic layer which is in contact with the lower electrode through the pixel aperture and emits light based on application of voltage; and
a second evaporation device forming an upper electrode which covers the organic layer and is in contact with the lower portion of the partition for the substrate, wherein
the organic layer includes a first thin film,
the first evaporation device comprises a first evaporation source used to form the first thin film,
the second evaporation device comprises a second evaporation source used to form the upper electrode,
the first evaporation source comprises a first nozzle which emits a vaporized material in a first evaporation direction, and a first shield which protrudes from the first nozzle,
the second evaporation source comprises a second nozzle which emits a vaporized material in a second evaporation direction,
the second evaporation direction inclines to a first lateral direction with respect to a normal direction of the substrate, and
the first shield has a shape in which a height on a first lateral direction side of the first nozzle is greater than a height on a second lateral direction side opposite to the first lateral direction side.

(28) The manufacturing equipment of the above (27), wherein
the organic layer includes a second thin film,
the first evaporation device comprises a third evaporation source used to form the second thin film,
the third evaporation source comprises a third nozzle which emits a vaporized material in a third evaporation direction, and a second shield which protrudes from the third nozzle, and
the second shield has a shape in which a height on a first lateral direction side of the third nozzle is equal to a height on a second lateral direction side of the third nozzle.

(29) The manufacturing equipment of the above (28), wherein
the second shield surrounds the third nozzle and has a uniform height over a whole circumference of the third nozzle.

(30) The manufacturing equipment of the above (28), wherein
the first thin film is one of a hole transport layer, an electron blocking layer, a light emitting layer, a hole blocking layer, an electron transport layer and an electron injection layer, and
the second thin film is a hole injection layer.

(31) The manufacturing equipment of the above (27), wherein
the organic layer consists of a plurality of thin films including the first thin film, and
each of a plurality of evaporation sources used to form the thin films comprises a nozzle which emits a vaporized material, and a shield having a shape in which a height on a first lateral direction side of the nozzle is greater than a height on a second lateral direction side.

What is claimed is:

1. A display device comprising:
a substrate;
a lower electrode provided above the substrate;
a rib having a pixel aperture which overlaps the lower electrode;
a partition which has a conductive lower portion provided on the rib and an upper portion protruding from a side surface of the lower portion;
an organic layer which is in contact with the lower electrode through the pixel aperture and emits light based on application of voltage; and
an upper electrode which covers the organic layer and is in contact with the lower portion of the partition, wherein
the partition has first and second partitions which are provided such that the pixel aperture is interposed between the first and second partitions,
the upper portion of the first partition has a first end portion which overlaps the organic layer and the upper electrode,
the upper portion of the second partition has a second end portion which overlaps the organic layer and the upper electrode,
a thickness of the organic layer immediately under the first end portion is less than a thickness of the organic layer immediately under the second end portion, and
a thickness of the upper electrode immediately under the first end portion is greater than a thickness of the upper electrode immediately under the second end portion.

2. The display device of claim 1, wherein
a contact area of the lower portion of the first partition and the organic layer is less than a contact area of the lower portion of the second partition and the organic layer.

3. The display device of claim 2, wherein
a contact area of the lower portion of the first partition and the upper electrode is greater than a contact area of the lower portion of the second partition and the upper electrode.

4. The display device of claim 1, wherein
the organic layer has a first layer and a second layer located on the first layer,
the first layer is spaced apart from the lower portions of the first and second partitions, and
the second layer is in contact with at least the lower portion of the second partition.

5. The display device of claim 4, wherein
the first layer includes a hole injection layer, and
the second layer includes a light emitting layer.

6. The display device of claim 1, further comprising a cap layer which covers the upper electrode.

7. The display device of claim 6, further comprising a sealing layer which continuously covers the cap layer, the first partition and the second partition.

8. The display device of claim 1, wherein
the lower portion includes:
a conductive bottom layer provided on the rib; and
a stem layer provided on the bottom layer, and
the upper electrode is in contact with at least the bottom layer of the lower portion of the first partition.

9. The display device of claim 8, wherein
an end portion of the bottom layer protrudes from a side surface of the stem layer.

10. A manufacturing method of a display device, including:
preparing a substrate including:
a lower electrode;
a rib having a pixel aperture which overlaps the lower electrode; and
a partition which has a conductive lower portion provided on the rib and an upper portion protruding from a side surface of the lower portion;
forming an organic layer which is in contact with the lower electrode through the pixel aperture and emits light based on application of voltage by vapor deposition; and
forming an upper electrode which covers the organic layer and is in contact with the lower portion of the partition by vapor deposition, wherein
the organic layer includes a first thin film,
a first evaporation direction, in which a first evaporation source used to form the first thin film emits a vaporized material, inclines with respect to a normal direction of the substrate, and
a second evaporation direction, in which a second evaporation source used to form the upper electrode emits a vaporized material, inclines to an opposite direction of the first evaporation direction with respect to the normal direction.

11. The manufacturing method of claim 10, wherein
the organic layer includes a second thin film, and
a third evaporation direction, in which a third evaporation source used to form the second thin film emits a vaporized material, is parallel to the normal direction.

12. The manufacturing method of claim 11, wherein
the first thin film is one of a hole transport layer, an electron blocking layer, a light emitting layer, a hole blocking layer, an electron transport layer and an electron injection layer, and
the second thin film is a hole injection layer.

13. The manufacturing method of claim 10, wherein
the organic layer consists of a plurality of thin films including the first thin film, and
in each of a plurality of evaporation sources used to form the thin films, an evaporation direction for emitting a vaporized material inclines to an opposite direction of the second evaporation direction with respect to the normal direction.

14. The manufacturing method of claim 10, wherein
the upper electrode includes a first conductive material and a second conductive material,
the vapor deposition of the upper electrode is co-evaporation at a co-evaporation ratio at which a ratio of the second conductive material is higher than a ratio of the first conductive material,
in the co-evaporation, the vaporized first conductive material is emitted from the second evaporation source in the second evaporation direction, and the vaporized second conducive material is emitted from a fourth evaporation source in a fourth evaporation direction,
the fourth evaporation direction inclines to a same direction as the second evaporation direction with respect to the normal direction, and
an angle formed by the fourth evaporation direction with the normal direction is greater than an angle formed by the second evaporation direction with the normal direction.

15. A manufacturing method of a display device, including:
preparing a substrate including:
a lower electrode;
a rib having a pixel aperture which overlaps the lower electrode; and
a partition which has a conductive lower portion provided on the rib and an upper portion protruding from a side surface of the lower portion;
forming an organic layer which is in contact with the lower electrode through the pixel aperture and emits light based on application of voltage by vapor deposition; and
forming an upper electrode which covers the organic layer and is in contact with the lower portion of the partition by vapor deposition, wherein
the organic layer includes a first thin film,
a first evaporation source used to form the first thin film comprises a first nozzle which emits a vaporized material in a first evaporation direction, and a first shield which protrudes from the first nozzle,
a second evaporation source used to form the upper electrode comprises a second nozzle which emits a vaporized material in a second evaporation direction,
the second evaporation direction inclines to a first lateral direction with respect to a normal direction of the substrate, and
the first shield has a shape in which a height on a first lateral direction side of the first nozzle is greater than a height on a second lateral direction side opposite to the first lateral direction side.

16. The manufacturing method of claim 15, wherein
the organic layer includes a second thin film,
a third evaporation source used to form the second thin film comprises a third nozzle which emits a vaporized material in a third evaporation direction, and a second shield which protrudes from the third nozzle, and
the second shield has a shape in which a height on a first lateral direction side of the third nozzle is equal to a height on a second lateral direction side of the third nozzle.

17. The manufacturing method of claim 16, wherein
the second shield surrounds the third nozzle and has a uniform height over a whole circumference of the third nozzle.

18. The manufacturing method of claim 16, wherein
the first thin film is one of a hole transport layer, an electron blocking layer, a light emitting layer, a hole blocking layer, an electron transport layer and an electron injection layer, and
the second thin film is a hole injection layer.

19. The manufacturing method of claim 15, wherein
the organic layer consists of a plurality of thin films including the first thin film, and
each of a plurality of evaporation sources used to form the thin films comprises a nozzle which emits a vaporized material, and a shield having a shape in which a height on a first lateral direction side of the nozzle is greater than a height on a second lateral direction side.

20. The manufacturing method of claim 15, wherein
the upper electrode includes a first conductive material and a second conductive material,
the vapor deposition of the upper electrode is co-evaporation at a co-evaporation ratio at which a ratio of the second conductive material is higher than a ratio of the first conductive material,
in the co-evaporation, the vaporized first conductive material is emitted from the second evaporation source in the second evaporation direction, and the vaporized second conductive material is emitted from a fourth evaporation source in a fourth evaporation direction,
the fourth evaporation direction inclines to a same direction as the second evaporation direction with respect to the normal direction, and
an angle formed by the fourth evaporation direction with the normal direction is greater than an angle formed by the second evaporation direction with the normal direction.
